(19) United States
(12) Patent Application Publication
(10) Pub. No.: US 2005/0130375 A1
(43) Pub. Date: Jun. 16, 2005

(54) Method of manufacturing flash memory device

(76) Inventor: Byoung Ki Lee, Kyungki-Do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/874,730

(22) Filed: Jun. 22, 2004

(30) Foreign Application Priority Data
Dec. 11, 2003 (KR) 2003-89980

(51) Int. Cl. H01L 21/20; H01L 21/336; C30B 1/00; H01L 21/36

(52) U.S. Cl. 438/260

(57) ABSTRACT

The present invention relates to a method for manufacturing a flash memory device. In a flash memory device using a self-aligned shallow trench isolation (SA-STI) scheme, an amorphous silicon layer is formed on a gate oxide film and a SPG process is implemented to change the amorphous silicon layer to a first polysilicon layer having large grains. It is thus possible to improve a thinning condition of the gate oxide film.

### BACKGROUND

1. Field of the Invention

The present invention relates to a method for manufacturing a flash memory device, and more specifically, to a method for manufacturing a flash memory device capable of improving a thinning condition of a gate oxide film in a flash memory device using a self-aligned shallow trench isolation (SA-STI) scheme.

2. Discussion of Related Art

Generally, a flash memory includes a high voltage transistor and a low voltage transistor for driving cells in view of a device. A typical method for manufacturing a flash memory device using a SA-STI scheme sequentially includes a screen oxide film formation process, a well/threshold voltage ion implantation process, a gate oxide film formation process (the gate oxide film is each formed in a cell region, a high voltage transistor region and a low voltage transistor region), an isolation process and a gate formation process.

Process steps from the formation of the gate oxide film to the formation of the floating gate in the cell region will be described in more detail as follows.

A semiconductor substrate in which a cell region, a high voltage transistor region and a low voltage transistor region are defined is provided. A high voltage gate oxide film of about 350 Å in thickness is formed on the semiconductor substrate of the high voltage transistor region by means of a gate oxide film formation process. A low voltage gate oxide film and a cell gate oxide film are thinly formed in thickness of about 80 Å on the semiconductor substrate of the low voltage transistor region and the cell region. A first polysilicon layer for a floating gate and a nitride film are formed on these gate oxide films. The nitride film, the first polysilicon layer and the semiconductor substrate are sequentially etched by means of an isolation process, thereby forming a plurality of trenches for isolation. The trenches are sufficiently filled by depositing HDP oxide and a plurality of isolation films are formed by means of chemical mechanical polishing (CMP) process. The first polysilicon layer between the field oxide layers is exposed by stripping the nitride layer remaining after the chemical mechanical polishing process. A cleaning process for stripping a native oxide film is performed and a second polysilicon layer for a floating gate is then formed. Next, a floating gate electrode is formed in the cell region by means of an etch process using a mask for the floating gate.

FIG. 1 is a graph showing the distribution of a cell threshold voltage (Vt). If Vt of the cell exceeds a reference voltage, it is a fail bit. This fail bit is called “pass disturb”. The cause of the “pass disturb” lies is lattice dislocation and local thinning of the gate oxide film.

Generally, if an interface and an interface meet, a mass transfer occurs in order to satisfy the surface tension between their interfacial energy.

FIG. 2 schematically shows a state where a phase α grain boundary and a phase αβ interface meet to make equilibrium, wherein each θ refers to a dihedral angle. FIG. 3 is a cross-sectional view of a flash memory device schematically shown to explain the mechanism that a thinning condition of a gate oxide film occurs in a SA-STI structure in the existing method for manufacturing the flash memory device. A gate oxide film 12 is formed on a semiconductor substrate 11. Amorphous silicon, partial crystalline silicon or crystalline silicon are deposited on the gate oxide film 12, thus forming a first polysilicon layer 13 for a floating gate. In the first polysilicon layer 13, a mass transfer does not occur in order to satisfy the dihedral angle since the deposition temperature is low when the amorphous silicon or the partial crystalline silicon is deposited but a mass transfer does occurs due to subsequent thermal processes (for example, an isolation film formation process, a dielectric film formation process, a gate poly oxidization process, a source/drain formation process, etc.) in order to satisfy the dihedral angle. In the first polysilicon layer 13, thinning (T) occurs in which the gate oxide film 12 is locally thin due to the mass transfer when grain boundaries are adjacent to each other since a grain (G) is small. There are problems that electrical properties and reliability of devices are lowered since a pass disturb fail bit is increased due to such a thinning condition.

### SUMMARY OF THE INVENTION

An object of the present invention is to provide a method for manufacturing a flash memory device capable of improving a thinning condition of a gate oxide film.

According to a preferred embodiment of the present invention, there is provided a method for manufacturing a flash memory device, comprising the steps of: forming gate oxide film and an amorphous silicon layer on a semiconductor substrate; implementing a SPG process to make the amorphous silicon layer a first polysilicon layer having large grains; forming a nitride film on the first polysilicon layer; and implementing an isolation process and a process of stripping the nitride film and forming a second polysilicon layer for a floating gate.

In the aforementioned of a method for manufacturing a flash memory device according to another embodiment of the present invention, the amorphous silicon layer is formed in thickness of 200 to 600 Å by using a Si₂H₄ gas as a source gas at a temperature of 420 to 520 Å.

In the aforementioned of a method for manufacturing a flash memory device according to another embodiment of the present invention, the SPG process is implemented at a temperature of 500 to 700 Å under a N₂ gas atmosphere.

### BRIEF DESCRIPTION OF THE DRAWINGS

FIG. 1 is a graph showing the distribution of a cell threshold voltage (Vt);

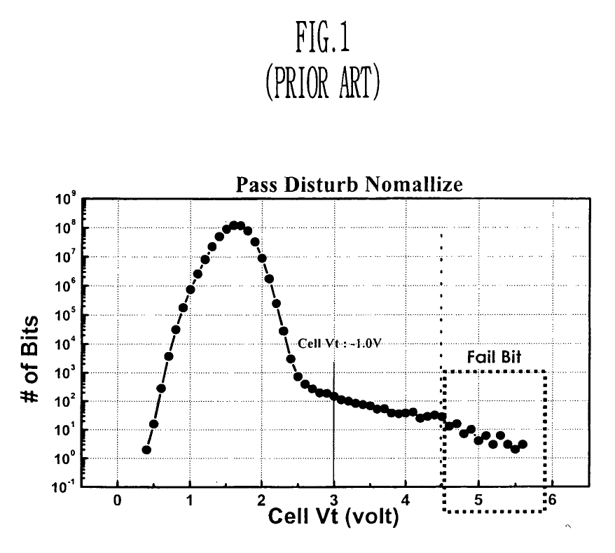

FIG. 2 schematically shows a state where a phase grain boundary and a phase interface meet to make equilibrium;

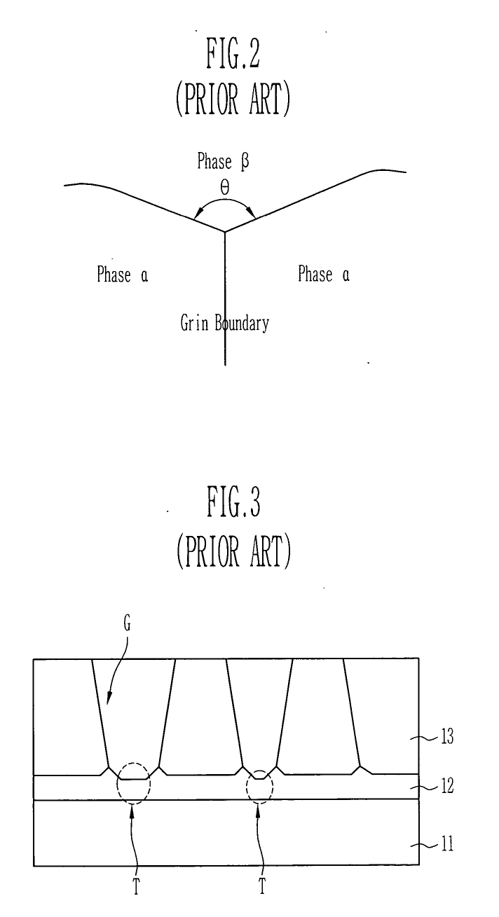

FIG. 3 is a cross-sectional view of a flash memory device schematically shown to explain the mechanism that a thinning condition of a gate oxide film occurs in a SA-STI structure in an existing method for manufacturing the flash memory device; and

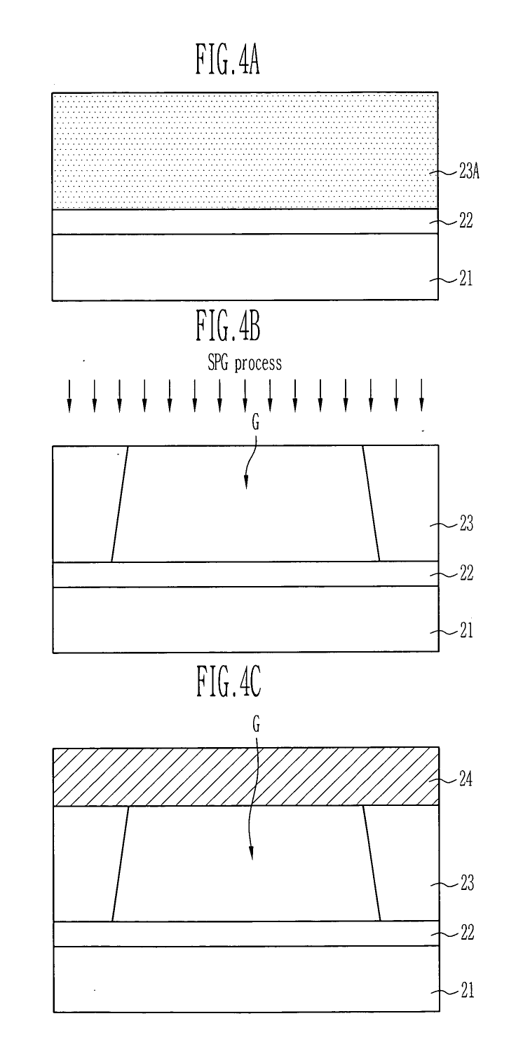

FIG. 4A to FIG. 4C are cross-sectional views of flash memory devices for explaining a method for manufacturing the flash memory device using a self-aligned shallow trench isolation scheme according to an embodiment of the present invention.

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

Meanwhile, in the case where it is described that one film is “on” the other film or a semiconductor substrate, the one film may directly contact the other film or the semiconductor substrate. Or, a third film may be intervened between the one film and the other film or the semiconductor substrate. Further, in the drawing, the thickness and size of each layer are exaggerated for convenience of explanation and clarity. Like reference numerals are used to identify the same or similar parts.

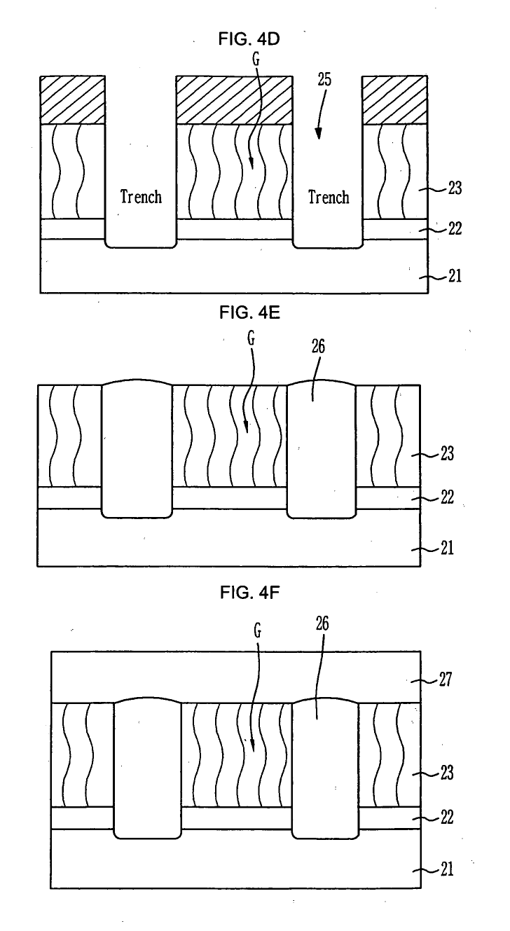

FIG. 4A to FIG. 4C are cross-sectional views of flash memory devices for explaining a method for manufacturing the flash memory device using a self-aligned shallow trench isolation scheme according to an embodiment of the present invention.

Referring to FIG. 4A, a semiconductor substrate 21 in which a cell region, a high voltage transistor region and a low voltage transistor region are defined is provided. A well formation process and a cell threshold voltage ion implantation process are performed for the semiconductor substrate 21. A gate oxide film 22 is formed on the semiconductor substrate 21. In the above, it is shown that the gate oxide film 22 is formed in the cell region or the low voltage transistor region but is not formed in the high voltage transistor region. The reason is that the gate oxide film formed in the high voltage transistor region does not significantly affect electrical properties of a device although a gate oxide film thinning condition occurs since its thickness is thick, over 300 Å. An amorphous silicon layer 23A is formed on the gate oxide film 22.

In the above, the amorphous silicon layer 23A is formed in thickness of 200 to 600 Å using a Si₂H₄ gas as a source gas at a temperature of 420 to 520 Å.

Referring to FIG. 4B, a SPG (Solid Phase Growth) process is carried out. During the SPG process, the amorphous silicon layer 23A is changed to a first polysilicon layer 23 for a floating gate having large grains (G) as a nuclear is created and particles are grown.

In the above, the SPG process is performed under a N₂ gas atmosphere at a temperature of 500 to 700° C. At this time, an average size of the grain (G) is over about 5 μm.

Referring to FIG. 4C, for an isolation process, a nitride film 24 is formed on the first polysilicon layer 23 in a LPCVD mode. If the nitride film 24 is formed in a state of the amorphous silicon layer 23A at a LPCVD deposition temperature of about over 500° C., a grain having very small particles are formed due to the deposition temperature, so that existing problems are caused. The nitride film 24, the first polysilicon layer 23, the gate oxide film 22 and the semiconductor substrate 21 are sequentially etched by means of the SA-STI (self-aligned shallow trench isolation) etch process, thereby forming a trench for isolation. After the trench is filled with oxide, a chemical mechanical polishing (CMP) process is performed to form an isolation film (not shown). Though not shown, typical processes of stripping the nitride film 24, forming a second polysilicon layer for a floating gate, forming a floating gate electrode in the cell region through an etch process using a mask for a floating gate and then forming a dielectric film and a control gate are performed, thereby completing a flash memory device.

According to the present invention described above, since grains of a first polysilicon layer for a floating gate are formed large, grain boundaries are not adjacent. A thinning condition of a gate oxide film is improved and a pass disturb fail bit is reduced. It is thus possible to improve electrical properties and reliability of a flash memory device.

1. A method for manufacturing a flash memory device, comprising the steps of:
forming a gate oxide film and an amorphous silicon layer on a semiconductor substrate;
performing a SPG process to change the amorphous silicon layer to a first polysilicon layer having large grains thereby preventing a reduction in the thickness of the gate oxide film;
forming a nitride film on the first polysilicon layer; and
implementing an isolation process, stripping the nitride film and then forming a second polysilicon layer for a floating gate.

2. The method as claimed in claim 1, wherein the amorphous silicon layer is formed in the thickness of 200 to 600 Å using a Si₂H₄ gas as a source gas at a temperature of 420 to 520° C.

3. The method as claimed in claim 1, wherein the SPG process is carried out at a temperature of 500 to 700° C. under a N₂ gas atmosphere.
